(19) United States
(12) Patent Application Publication
(10) Pub. No.: US 2010/0314740 A1
(43) Pub. Date: Dec. 16, 2010

(54) SEMICONDUCTOR PACKAGE, STACK MODULE, CARD, AND ELECTRONIC SYSTEM

(75) Inventors: Keun-ho CHOI, Gunpo-si (KR); Myung-kee CHUNG, Cheon An-si (KR); Kun-dae YEOM, Cheon An-si (KR); Kil-soo KIM, Hwasung-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/776,789

(22) Filed: May 10, 2010

(30) Foreign Application Priority Data
Jun. 15, 2009 (KR) 10-2009-0052942

(51) Int. Cl. H01L 25/065; H01L 23/52

(52) U.S. Cl. 257/686; 257/723; 257/690; 257/E23.141; 257/E25.013

(57) ABSTRACT

A multi-chip package device can include a plurality of integrated circuit device chips stacked on one another inside a multi-chip package including the device. The device can include an electrically isolated multi-chip support structure that is directly connected to first and second electrically active integrated circuit structures via respective first and second adhesive layers located on opposing sides of the electrically isolated multi-chip support structure.

### CROSS-REFERENCE TO RELATED APPLICATIONS

This application claims the benefit of Korean Patent Application No. 10-2009-0052942, filed on Jun. 15, 2009, in the Korean Intellectual Property Office, the disclosure of which is incorporated herein in its entirety by reference.

### BACKGROUND

The inventive concept relates to the field of electronics in general, and more particularly, to semiconductor packaging.

Semiconductor products typically are small and may be used to process large amounts of data. Due to current levels of integration of semiconductors, one type of semiconductor packaging that has been used is referred to as a stacked type semiconductor package. In a stacked type semiconductor package, a plurality of semiconductor chips may be stacked on one another.

### SUMMARY

According to an aspect of the inventive concept, a multi-chip package device can include a plurality of integrated circuit device chips stacked on one another inside a multi-chip package including the device. The device can include an electrically isolated multi-chip support structure that is directly connected to first and second electrically active integrated circuit structures via respective first and second adhesive layers located on opposing sides of the electrically isolated multi-chip support structure.

### BRIEF DESCRIPTION OF THE DRAWINGS

FIG. 1 is a cross-sectional view of a semiconductor package according to an embodiment of the inventive concept;

FIG. 2 is a plan view of a part of the semiconductor package of FIG. 1;

FIG. 3 is a cross-sectional view of a semiconductor package according to another embodiment of the inventive concept;

FIG. 4 is a cross-sectional view of a semiconductor package according to another embodiment of the inventive concept;

FIG. 5 is a cross-sectional view of a semiconductor package according to another embodiment of the inventive concept;

FIG. 6 is a cross-sectional view of a semiconductor package according to another embodiment of the inventive concept;

FIG. 7 is a plan view of a part of the semiconductor package of FIG. 6;

FIG. 8 is a cross-sectional view of a semiconductor package according to another embodiment of the inventive concept;

FIG. 9 is a cross-sectional view of a semiconductor package according to another embodiment of the inventive concept;

FIG. 10 is a cross-sectional view of a semiconductor package according to another embodiment of the inventive concept;

FIG. 11 is a cross-sectional view of a semiconductor package according to another embodiment of the inventive concept;

FIG. 12 is a cross-sectional view of a semiconductor package according to another embodiment of the inventive concept;

FIG. 13 is a cross-sectional view of a stack module according to an embodiment of the inventive concept;

FIG. 14 is a cross-sectional view of a stack module according to another embodiment of the inventive concept;

FIG. 15 is a cross-sectional view of a semiconductor package according to another embodiment of the inventive concept;

FIGS. 16 through 18 and FIGS. 20 through 22 are plan views illustrating supporting members of semiconductor packages, according to embodiments of the inventive concept;

FIG. 19 is a perspective view of the supporting member of FIG. 18;

FIG. 23 is a plan view of a card according to an embodiment of the inventive concept;

FIG. 24 is a schematic block diagram of a memory card according to an embodiment of the inventive concept;

FIG. 25 is a block diagram of an electronic system according to an embodiment of the inventive concept;

FIGS. 26 through 29 are cross-sectional views illustrating a method of fabricating a semiconductor package according to an embodiment of the inventive concept; and

FIGS. 30 through 32 are cross-sectional views illustrating a method of fabricating a semiconductor package according to another embodiment of the inventive concept.

### DETAILED DESCRIPTION OF THE EMBODIMENTS

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims.

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

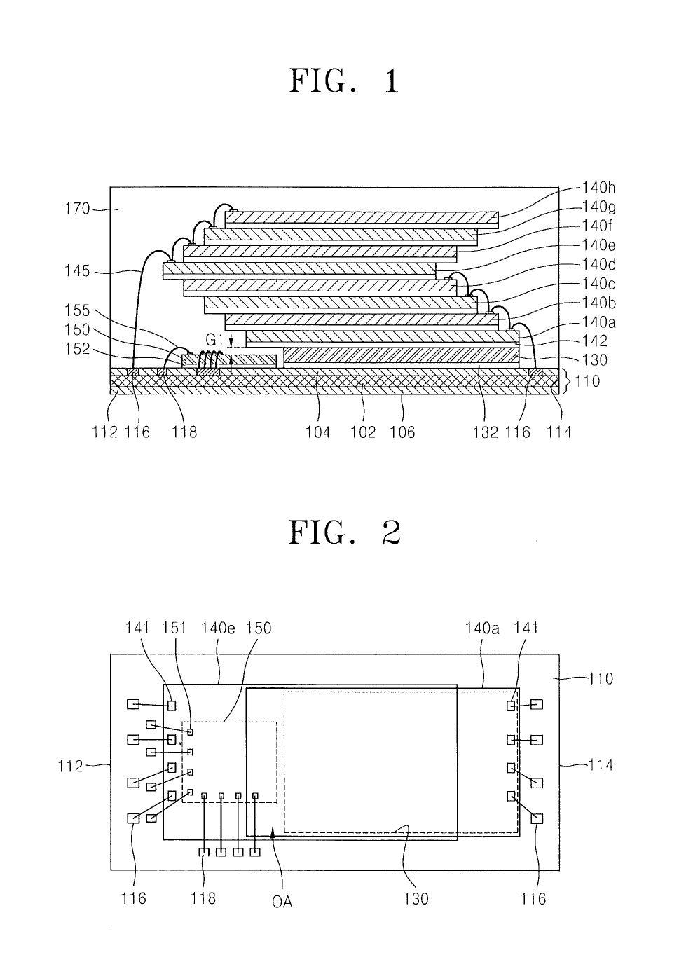

FIG. 1 is a cross-sectional view of a semiconductor package according to an embodiment of the inventive concept, and FIG. 2 is a plan view of a part of the semiconductor package of FIG. 1. Referring to FIGS. 1 and 2, a substrate 110 is provided. For example, the substrate 110 may be a printed circuit board (PCB), a flexible substrate, a tape substrate, or the like. The substrate 110 includes a core board 102, a first resin layer 104 which is formed on an upper surface of the core board 102, and a second resin layer 106 which is formed on a lower surface of the core board 102. The substrate 110 has first and second sidewalls 112 and 114 which are opposite to each other.

First electrode fingers 116 and second electrode fingers 118 are further formed in the first resin layer 104. For example, the first and second electrode fingers 116 and 118 are arranged on the core board 102 and exposed from a first resin layer 104. The substrate 110 may further include a circuit pattern (not shown) which electrically connects some of the first electrode fingers 116 to some of the second electrode fingers 118. The numbers and arrangements of first and second electrode fingers 116 and 118 are exemplarily illustrated and thus do not limit the scope of this embodiment.

A plurality of first semiconductor chips 140a through 140h are stacked above the substrate 110 using adhesive members 142. The first semiconductor chips 140a through 140h include integrated circuits (ICs), and are sometimes referred to herein as IC device chips. For example, the ICs may be memory circuits or logic circuits. First electrode pads 140 are formed on upper surfaces, i.e., active surfaces, of the first semiconductor chips 140a through 140h and are respectively connected to the ICs.

The first semiconductor chips 140a through 140h may be the same types of products or different types of products. For example, all of the first semiconductor chips 140a through 140h may be memory chips. The memory chips may include various types of memory circuits, e.g., dynamic random access memories (DRAMs), static random access memories (SDRAMs), flash memories, phase-change RAMs (PRAMs), resistive RAMs (ReRAMs), ferroelectrics RAMs (FeRAMs), or magnetoresistive RAMs (MRAMs). In this case, the first semiconductor chips 140a through 140h may have the same sizes or different sizes depending on the type of memory circuits. The number of first semiconductor chips 140a through 140h is exemplarily illustrated and thus does not limit the scope of this embodiment.

The first semiconductor chips 140a through 140h have sequential offset arrangements and thus expose the electrode pads 140. For example, the first semiconductor chips 140a through 140e may be sequentially offset toward the first sidewall 112 of the substrate 110, and the first semiconductor chips 140f through 140h may be sequentially offset toward the second sidewall 114 of the substrate 110. The sequential offset arrangements of the first semiconductor chips 140a through 140h are exemplarily illustrated and thus do not limit the scope of this embodiment. For example, the first semiconductor chips 140a through 140h may all be offset in one direction or may be repeatedly offset along two directions as described above.

Accordingly, as illustrated in FIG. 1 the first semiconductor chips 140a through 140h are in a stair-step arrangement. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

The first semiconductor chips 140a through 140h are electrically connected to the substrate 110 through first connecting members 145. For example, the first connecting members 145 directly connect the first electrode pads 141 of the first semiconductor chip 140a to the first electrode fingers 116 of the substrate 110 and connect the first electrode pads 141 of the first semiconductor chips 140b, 140c, and 140d to one another. The first connecting members 145 also directly connect the first electrode pads 141 of the first semiconductor chip 140e to the first electrode fingers 116 of the substrate 110 and connect the first electrode pads 141 of the first semiconductor chips 140f, 140g, and 140h to one another. The first connecting members 145 may be bonding wires.

A supporting member (sometimes referred to herein as a support structure) 130 is arranged between the substrate 110 and the first semiconductor chips 140a through 140h. For example, the supporting member 130 is interposed between the substrate 110 and the first semiconductor chip 140a which is arranged on a lowermost layer of the stack of IC device chips. The supporting member 130 is adhered onto the substrate 110 using an adhesive member 132, which is sometimes referred to herein as an adhesive layer.

The supporting member 130 supports the first semiconductor chips 140a through 140h. The supporting member 130 is electrically isolated from the substrate 110. Thus, the supporting member 130 is distinguished from the first semiconductor chips 140a through 140h which are electrically connected to the substrate 110. The supporting member 130 is also electrically isolated from the first semiconductor chips 140a through 140h.

The supporting member 130 may be formed of various kinds of materials. For example, the supporting member 130 may be a dummy chip which does not include an IC. If ICs are formed on a semiconductor wafer to fabricate the first semiconductor chips 140a through 140h, the dummy chip may be the semiconductor wafer on which the ICs are not formed. If back grinding is not performed with respect to the semiconductor wafer, the dummy chip may be thicker than each of the first semiconductor chips 140a through 140h.

According to an aspect of the inventive concept, the supporting member 130 may be a PCB or an insulating substrate. The supporting member 130 may include an interposer. As another aspect of the inventive concept, the supporting member 130 may be a semiconductor chip which includes an IC. Since the supporting member 130 is electrically isolated from the substrate 100 in this case, the IC of the supporting member 130 does not participate in an operation of the semiconductor package, and therefore may be electrically inactive.

The supporting member 130 is offset from at least one sidewall of the first semiconductor chip 140a toward an inner direction. Thus, a part of a lower surface of the first semiconductor chip 140a is not covered with the supporting member 130 and thus is exposed, and an offset area “OA” is defined under the exposed part of the lower surface of the first semiconductor chip 140a. A planar size of the supporting member 130 is smaller than a planar size of the first semiconductor chip 140a so that the supporting member 130 does not increase the size of the semiconductor package. Here, the planar size is referred to as a size as seen above the substrate 110, i.e., a cross-section size parallel with the substrate 110. The planar size may be referred to as a footprint in some of embodiments of the inventive concept.

Accordingly, opposite sidewalls of the supporting member 130 are arranged with sidewalls of the first semiconductor chip 140a respectively corresponding to the opposite sidewalls of the supporting member 130 or are offset toward an inner direction. For example, a whole part of an upper surface of the supporting member 130 is covered with the lower surface of the first semiconductor chip 140a. In other words, a whole part of the supporting member 130 vertically overlaps with a part of the first semiconductor chip 140. In this case, the supporting member 130 is hidden by the first semiconductor chip 140a and thus is not seen from above the substrate 110. Thus, the supporting member 130 can affect a height of the semiconductor package but not a planar size of the semiconductor package.

According to a modified example of this embodiment, the supporting member 130 may be offset from at least one sidewall of the first semiconductor chip 140a and may not be wholly covered with the first semiconductor chip 140a. Therefore, a part of the upper surface of the supporting member 130 may be exposed from the first semiconductor chip 140a.

A second semiconductor chip 150 is stacked above the substrate 110 using an adhesive member 152 which is interposed between the semiconductor chip 150 and the substrate 110. The second semiconductor chip 150 includes an IC. For example, the semiconductor chip 150 may be a logic chip which includes a logic circuit. The logic chip may be a controller which controls memory chips. The second semiconductor chip 150 includes second electrode pads 151 which are electrically connected to the logic circuit. In this case, the second semiconductor chip 150 has a smaller planar size than each of the first semiconductor chips 140a through 140h. Thus, the second electrode pads 151 are arranged more densely than the first electrode pads 141. In addition, as the second semiconductor chip 150 has a complicated function, the number of second electrode pads 151 can increase. As a result, the second electrode pads 151 may be much more densely arranged.

The second semiconductor chip 150 is substantially arranged on a same level with the supporting member 130 arranged under the first semiconductor chip 140a. For example, the second semiconductor chip 150 is disposed in the offset area OA under the first semiconductor chip 140a and is adjacent to the supporting member 130. Thus, at least a part of the second semiconductor chip 150 vertically overlaps with a part of the first semiconductor chip 140a. A planar size and an offset degree of the supporting member 130 are controlled to control an overlap degree between the second semiconductor chip 150 and the first semiconductor chip 140a. This overlap arrangement reduces an effect of a planar size of the second semiconductor chip 150 on the planar size of the semiconductor package.

A whole part of the second semiconductor chip 150 vertically overlaps with a part of the first semiconductor chip 140e which is offset most distantly from the first sidewall 112 of the substrate 110. In this case, the second semiconductor chip 150 is substantially hidden by the first semiconductor chips 140a through 140h when viewed from above the substrate 110. Thus, the second semiconductor chip 150 does not increase the planar size of the semiconductor package.

However, according to a modified example of this embodiment, the semiconductor chip 150 may not be wholly covered with the first semiconductor chip 140e. In this case, a protruding part of the second semiconductor chip 150 may be minimized to minimize an increase in the planar size of the semiconductor package.

The second semiconductor chip 150 is electrically connected to the substrate 110 through second connecting members 155. For example, the second connecting members 155 directly connect the second electrode pads 151 to the second electrode fingers 118. The second connecting members 155 may be bonding wires. A height of the supporting member 130 is higher than a height of the second semiconductor chip 150 to easily arrange the second connecting members 155. Thus, a gap G1 is formed between the second semiconductor chip 150 and the first semiconductor chip 140a.

Some of the second electrode fingers 118 are electrically connected to the first electrode fingers 116 through an internal circuit (not shown) of the substrate 110. Thus, the second semiconductor chip 150 is electrically connected to the first semiconductor chips 140a through 140h.

A molding member 170 is formed on the substrate 110 and covers the first semiconductor chips 140a through 140h and the second semiconductor chip 150. For example, the molding member 170 may include an insulating resin, e.g., an epoxy molding compound.

In this embodiment, the second semiconductor chip 150 is stacked right above the substrate 110. Thus, heights of the second connecting members 155 are lowered than when the semiconductor chip 150 is arranged above the first semiconductor chip 140h which is arranged on an uppermost layer. As a result, the second connecting members 155 are easily connected to the second electrode pads 15 which are densely arranged. Since the heights of the second connecting members 155 are lowered, there is a lower probability that the second connecting members 155 will short-circuit due to wire swiping in a subsequent molding step.

Accordingly, the second semiconductor chip 150 is arranged right above the substrate 110 and thus improves connection reliability between the second semiconductor chip 150 and the substrate 110. Also, the semiconductor chip 150 overlaps with parts of the first semiconductor chips 140a through 140h and prevents an increase in the footprint of the semiconductor package. As a result, the planar size of the semiconductor package is reduced.

Therefore, as illustrated by FIGS. 1 and 2, the electrically isolated supporting member is smaller than, for example, the electrically active first semiconductor chip 140a in a first dimension (for example the horizontal dimension) so that a portion of the electrically active first semiconductor chip 140a is cantilevered over the electrically active substrate 110 to form a recess between the cantilevered portion and the substrate. Further, the recess is bounded in the horizontal dimension by a sidewall of the electrically isolated supporting member. As shown the recess can provide spacing for the placement of the second semiconductor chip 150 on the substrate 110 without increasing a size of the package.

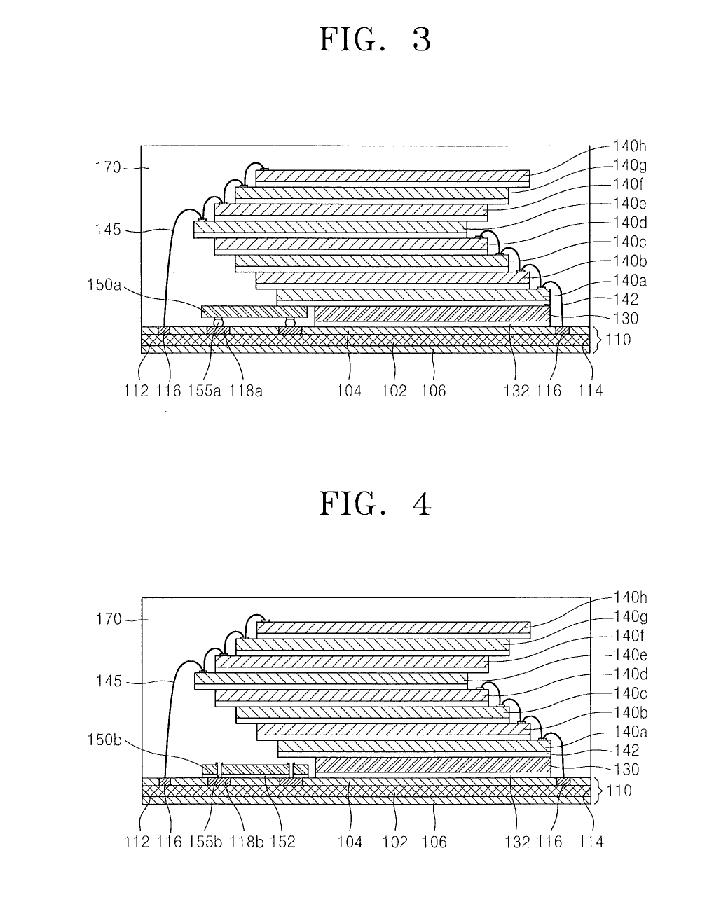

FIG. 3 is a cross-sectional view of a semiconductor package according to another embodiment of the inventive concept. The semiconductor package of this embodiment has a similar structure to the semiconductor package of FIG. 1 except for some elements, and thus repeated descriptions are omitted.

Referring to FIG. 3, a second semiconductor chip 150a is of a flip chip type and stacked above a substrate 100. The second semiconductor chip 150a is arranged so that an active surface of the semiconductor chip 150a faces the substrate 110 and is connected to second bonding fingers 118a of the substrate 110 through bumps 155a.

Accordingly, as illustrated in FIG. 3 the first semiconductor chips 140a through 140h are in a stair-step arrangement. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

Alternatively, sizes of the bumps 155a may be controlled so that the second semiconductor chip 150a is adhered onto a first semiconductor chip 140a using an adhesive member 142. Since a supporting member 130 and the second semiconductor chip 150a support first semiconductor chips 140a through 140h together in this case, solidity of the semiconductor package can be increased.

FIG. 4 is a cross-sectional view of a semiconductor package according to another embodiment of the inventive concept. The semiconductor package of this embodiment has a similar structure to the semiconductor package of FIG. 1 except for some elements, and thus repeated descriptions are omitted. Accordingly, as illustrated in FIG. 4 the first semiconductor chips 140a through 140h are in a stair-step arrangement. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

Referring to FIG. 4, a second semiconductor chip 150b is electrically connected to a substrate 110 through second connecting members 155b which penetrate through the second semiconductor chip 150b. The second connecting members 155b may be referred to as through electrodes.

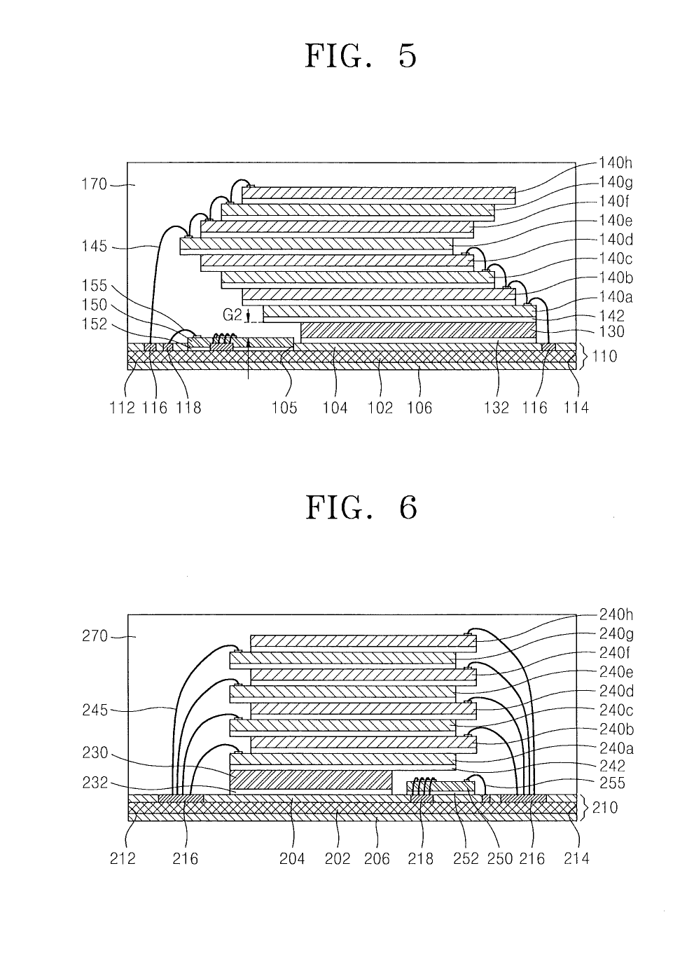

FIG. 5 is a cross-sectional view of a semiconductor package according to another embodiment of the inventive concept. The semiconductor package of this embodiment has a similar structure to the semiconductor package of FIG. 1 except for some elements, and thus repeated descriptions are omitted.

Accordingly, as illustrated in FIG. 5 the first semiconductor chips 140a through 140h are in a stair-step arrangement. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

Referring to FIG. 5, a substrate 110 includes an opening 105 which is formed inside a first resin layer 104. A second semiconductor chip 150 is adhered onto a part of a core board 102 in the opening 105, using an adhesive member 152. Thus, the second semiconductor chip 150 is arranged on a lower level than a supporting member 130. In this case, a gap “G2” formed between the second semiconductor chip 150 and the first semiconductor chip 140a is greater than the gap “G1” formed between the second semiconductor chip 150 and the first semiconductor chip 140a shown in FIG. 1. As a result, second connecting members 155 may be more easily formed.

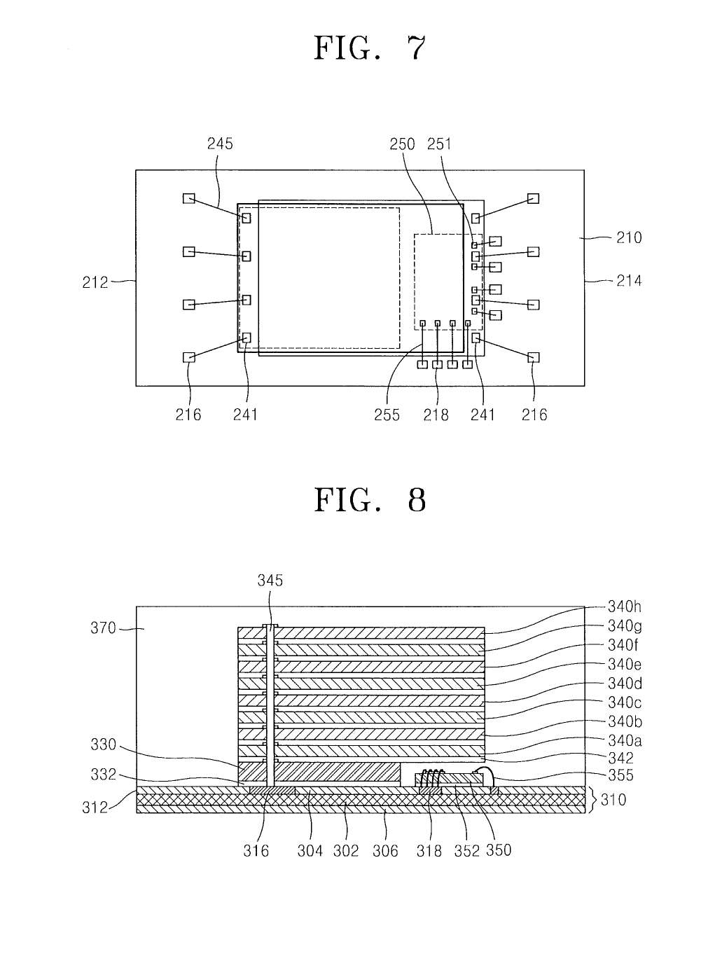

FIG. 6 is a cross-sectional view of a semiconductor package according to another embodiment of the inventive concept, and FIG. 7 is a plan view of a part of the semiconductor package of FIG. 6. Referring to FIGS. 6 and 7, a substrate 210 is provided. The substrate 210 includes a core board 202, a first resin layer 204 which is formed on an upper surface of the core board 202, and a second resin layer 206 which is formed on a lower surface of the core board 202. First electrode fingers 216 and second electrode fingers 218 are arranged inside the first resin layer 204. The description of the substrate 110 of FIG. 1 may be further referred to for the description of the substrate 210.

A plurality of first semiconductor chips 240a through 240h are stacked above the substrate 210 using adhesive members 242 which are interposed among the first semiconductor chips 240a through 240h. The first semiconductor chips 240a through 240h are offset in a zigzag pattern or staggered form that is different from that of the first semiconductor chips 140a through 140h shown in FIG. 1. Thus, first electrode pads 241 of the first semiconductor chips 240a, 240c, 240e, and 240g are arranged adjacent to a first sidewall 212 of the substrate 210, and first electrode pads 241 of the first semiconductor chips 240b, 240d, 240f, and 240h are arranged adjacent to a second sidewall 214 of the substrate 210.

The first semiconductor chips 240a through 240h are electrically connected to the substrate 210 through first connecting members 245. For example, the first connecting members 245 directly connect the first electrode pads 241 of the first semiconductor chips 240a through 240h to the first electrode fingers 216 of the substrate 210. For example, the first connecting members 245 may be bonding wires.

The descriptions of the first semiconductor chips 140a through 140h of FIG. 1 may be further referred to for the descriptions of the first semiconductor chips 240a through 240h.

A supporting member 230 is stacked above the substrate 210 using an adhesive member 232 on a surface of the substrate 210. The sidewall of the supporting member 230 is aligned to a sidewall of the first semiconductor chip 240a toward the first sidewall 212 of the substrate 210. The description of the supporting member 130 of FIG. 1 may be further referred to for the description of the supporting member 230.

A second semiconductor chip 250 is stacked above the substrate 210 using an adhesive member 252 which is interposed between the second semiconductor chip 250 and the substrate 210. The second semiconductor chip 250 is electrically connected to the substrate 210 through second connecting members 255. The second connecting members 255 directly connect second electrode pads 251 of the second semiconductor chip 250 to the second electrode fingers 218 of the substrate 210. For example, the second connecting members 255 may be bonding wires.

At least a part of the second semiconductor chip 250 vertically overlaps with a part of the first semiconductor chip 240a. A whole part of the second semiconductor chip 250 vertically overlaps with a part of the first semiconductor chip 240b. The description of the second semiconductor chip 150 of FIG. 1 may be further referred to for the description of the second semiconductor chip 250.

Accordingly, as illustrated in FIG. 6 the first semiconductor chips 240a through 240h are in a stair-step arrangement, which alternatingly reverses direction. In particular, the stair-step arrangement includes two steps in the horizontal direction, then is reversed in the opposite direction for two steps, which is then repeated. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

According to modified examples of this embodiment, the second semiconductor chip 250 may be replaced with the second semiconductor chip 150a of FIG. 3 or the second semiconductor chip 150b of FIG. 4.

A molding member 270 is formed on the substrate 210 and covers the first semiconductor chips 240a through 240h and the second semiconductor chip 250.

FIG. 8 is a cross-sectional view of a semiconductor package according to another embodiment of the inventive concept. The semiconductor package of this embodiment has a similar structure to the semiconductor package of FIG. 1 except for some elements, and thus repeated descriptions will be omitted.

Referring to FIG. 8, a substrate 310 is provided. The substrate 310 includes a core board 302, a first resin layer 304 which is formed on an upper surface of the core board 302, and a second resin layer 306 which is formed on a lower surface of the core board 302. First electrode fingers 316 and second electrode fingers 318 are arranged inside the first resin layer 304. The description of the substrate 110 of FIG. 1 may be further referred to for the description of the substrate 310.

A plurality of first semiconductor chips 340a through 340h are stacked above the substrate 310 using adhesive members 342 which are interposed among the first semiconductor chips 340a through 340h. The first semiconductor chips 340a through 340h are arranged so that their ends are vertically aligned, differently from the first semiconductor chips 140a through 140h of FIG. 1. The first semiconductor chips 340a through 340h are electrically connected to the substrate 310 through a first connecting member 345. For example, the first connecting member 345 penetrates through first electrode pads (not shown) of the first semiconductor chips 340a through 340h and are connected to first electrode fingers 316 of the substrate 310. In this case, the first connecting member 345 may be referred to as a through electrode.

The descriptions of the first semiconductor chips 140a through 140h of FIGS. 1 and 2 may be further referred to for the descriptions of the first semiconductor chips 340a through 340h.

A supporting member 330 is stacked above the substrate 310 on an adhesive member 332. The supporting member 330 is offset from the first semiconductor chip 340a toward a first sidewall 312 of the substrate 310. The description of the supporting member 130 of FIG. 1 may be further referred to for the description of the supporting member 33.

A second semiconductor chip 350 is stacked above the substrate 310 using an adhesive member 352 which is interposed between the second semiconductor chip 350 and the substrate 310. The second semiconductor chip 350 is electrically connected to the substrate 310 through second connecting members 355. The second connecting members 355 directly connect second electrode pads (not shown) of the second semiconductor chip 350 to second electrode fingers 318 of the substrate 310. For example, the second connecting members 355 may be bonding wires. A whole part of the second semiconductor chip 350 vertically overlaps with a part of the first semiconductor chip 340a. The description of the second semiconductor chip 150 of FIG. 1 may be further referred to for the description of the second semiconductor chip 350.

According to modified examples of this embodiment, the second semiconductor chip 350 may be replaced with the second semiconductor chip 150a of FIG. 3 or the second semiconductor chip 150b of FIG. 4.

A molding member 370 is formed on the substrate 310 and covers the first semiconductor chips 340a through 340h and the second semiconductor chip 350.

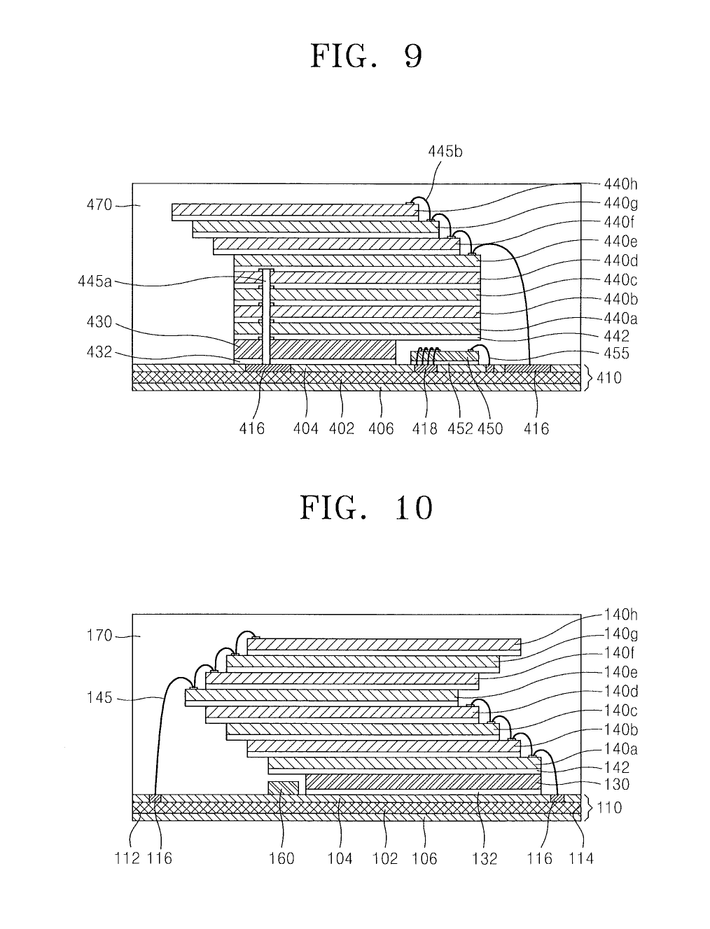

FIG. 9 is a cross-sectional view of a semiconductor package according to another embodiment of the inventive concept. The semiconductor package of this embodiment has a similar structure to the semiconductor package of FIG. 1 except for some elements, and thus repeated descriptions will be omitted.

Referring to FIG. 9, a substrate 410 is provided. The substrate 410 includes a core board 402, a first resin layer 404 which is formed on an upper surface of the core board 402, and a second resin layer 406 which is formed on a lower surface of the core board 402. First electrode fingers 416 and second electrode fingers 418 are arranged inside the first resin layer 404. The description of the substrate 110 of FIG. 1 may be further referred to for the description of the substrate 410.

A plurality of first semiconductor chips 440a through 440h are stacked above the substrate 410 using adhesive members 442 which are interposed among the first semiconductor chips 440a through 440h. Differently from the first semiconductor chips 140a through 140h of FIG. 1, the first semiconductor chips 440a, 440b, 440c, 440d, and 440e are vertically aligned, and the first semiconductor chips 440f, 440g, and 440h are sequentially offset from the first semiconductor chip 440e.

The first semiconductor chips 440a, 440b, 440c, 440d, and 440e are electrically connected to the substrate 410 through a first connecting member 445a. The first connecting member 445a penetrates through first electrode pads (not shown) of the first semiconductor chips 440a, 440b, 440c, 440d, and 440e and is connected to the first electrode fingers 416 of the substrate 410. In this case, the first connecting member 445a may be referred to as a through electrode. The first semiconductor chips 440f, 440g, and 440h are connected to the first electrode fingers 416 of the substrate 410 through first connecting members 445b.

The descriptions of the first semiconductor chips 140a through 140h of FIG. 1 may be further referred to for the descriptions of the first semiconductor chips 440a through 440h.

A supporting member 430 is stacked above the substrate 410 using an adhesive member 432. The descriptions of the supporting member 130 of FIG. 1 and the supporting member 330 of FIG. 8 may be further referred to for the description of the supporting member 430.

A second semiconductor chip 450 is stacked above the substrate 410 using an adhesive member 452 which is interposed between the second semiconductor chip 450 and the substrate 410. The second semiconductor chip 45 is electrically connected to the substrate 410 through second connecting members 455. The second connecting members 455 directly connect second electrode pads (not shown) of the second semiconductor chip 450 to the second electrode fingers 418 of the substrate 410. The description of the second semiconductor chip 150 of FIG. 1 may be further referred to for the description of the second semiconductor chip 450.

Accordingly, as illustrated in FIG. 9 the first semiconductor chips 440d through 440h are in a stair-step arrangement. The stair-step arrangement can provide that the sidewalls of these chips are progressively offset from one another in a first dimension (such as the horizontal dimension) so that respective pads located on the chips are sufficiently exposed to allow for contact by, for example, wires.

According to modified examples of this embodiment, the second semiconductor chip 450 may be replaced with the second semiconductor chip 150a of FIG. 3 or the second semiconductor chip 150b of FIG. 4.

A molding member 470 is formed on the substrate 410 and covers the first semiconductor chips 440a through 440h and the second semiconductor chip 450.

FIG. 10 is a cross-sectional view of a semiconductor package according to another embodiment of the inventive concept. The semiconductor package of this embodiment has a similar structure to the semiconductor package of FIG. 1 except for some elements, and thus repeated descriptions will be omitted.

Accordingly, as illustrated in FIG. 10 the first semiconductor chips 140a through 140h are in a stair-step arrangement. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

Referring to FIG. 10, instead of the second semiconductor chip 150 of FIG. 1, a passive device 160 is formed on a substrate 110. The passive device 160 contrasts with an active device and may include a resistor, a capacitor, or an inductor.

At least a part of the passive device 160 vertically overlaps with a part of a semiconductor chip 140a. A whole part of the passive device 160 vertically overlaps with a part of a first semiconductor chip 140e. Thus, the passive device 160 is wholly covered with first semiconductor chips 140a through 140h when viewed from above the substrate 110. Thus, the passive device 160 does not affect a planar size of the semiconductor package.

FIG. 11 is a cross-sectional view of a semiconductor package according to another embodiment of the inventive concept. The semiconductor package of this embodiment has a similar structure to the semiconductor package of FIG. 1 except for some elements, and thus repeated descriptions will be omitted.

Accordingly, as illustrated in FIG. 11 the first semiconductor chips 140a through 140h are in a stair-step arrangement. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

Referring to FIG. 11, a passive device 160 is further formed on a substrate 110. The passive device 160 is arranged opposite to a second semiconductor chip 150 so that a supporting member 130 is positioned between the passive device 160 and the second semiconductor chip 150. A whole part of the passive device 160 vertically overlaps with a part of a semiconductor chip 140a. For example, because the supporting member 130 is centered on a central part of a first semiconductor 140a, a planar size of the supporting member 130 can be smaller than a planar size of the first semiconductor chip 140a. Thus, spaces are formed beside sidewalls of the supporting member 130 and right under the first semiconductor chip 140a. The second semiconductor chip 150 and the passive device 160 are arbitrarily arranged in the spaces.

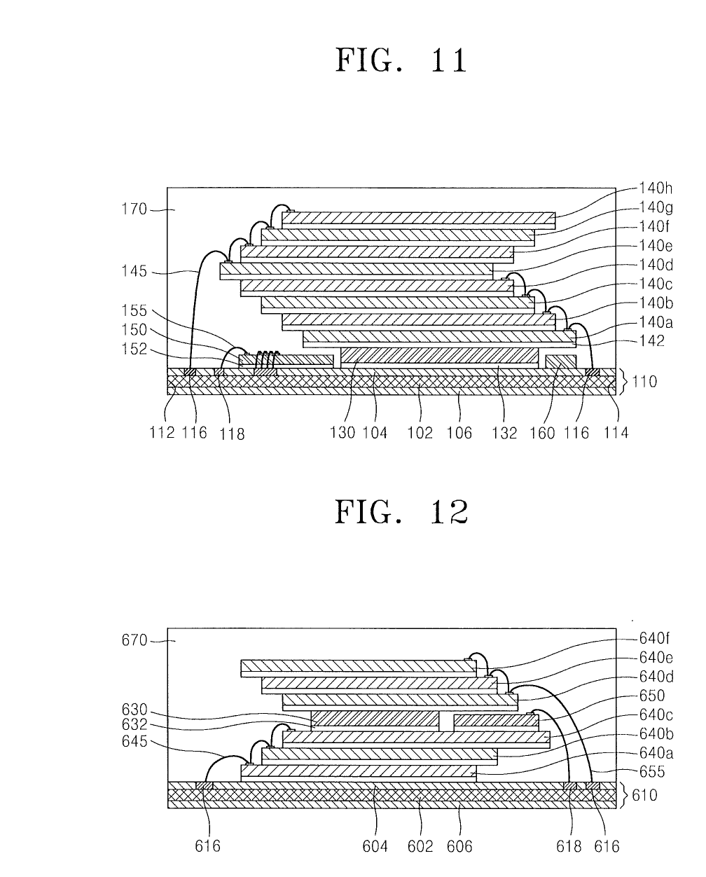

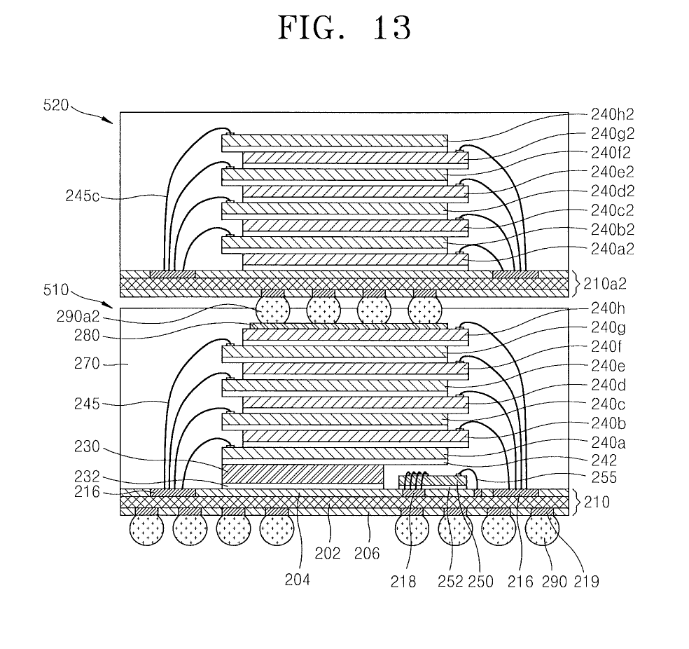

FIG. 12 is a cross-sectional view of a semiconductor package according to another embodiment of the inventive concept. The semiconductor package of this embodiment has a similar structure to the semiconductor package of FIG. 1 except for some elements, and thus repeated descriptions will be omitted.

Accordingly, as illustrated in FIG. 12 the first semiconductor chips 640a through 640f are in a stair-step arrangement. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

Referring to FIG. 12, a substrate 610 is provided. The substrate 610 includes a core board 602, a first resin layer 604 which is formed on an upper surface of the core board 602, and a second resin layer 606 which is formed on a lower surface of the core board 602. First electrode fingers 616 and second electrode fingers 618 are arranged inside the first resin layer 604. The description of the substrate 110 of FIG. 1 may be further referred to for the description of the substrate 610.

First semiconductor chips 640a through 640f are sequentially stacked above the substrate 610. The first semiconductor chips 640a through 640f are offset toward at least one sidewall of the substrate 610. The first semiconductor chips 640a through 640f are electrically connected to the first electrode fingers 616 of the substrate 610 through first connecting members 645.

A supporting member 630 is interposed between the first semiconductor chips 640c and 640d. The supporting member 630 is adhered onto the first semiconductor chip 640c using an adhesive member 632 which is interposed between the supporting member 630 and the first semiconductor chip 640c. A planar size of the supporting member 630 is smaller than a planar size of the first semiconductor chip 640d. The supporting member 630 is covered with the first semiconductor chip 640d. The description of the supporting member 130 of FIG. 1 may be further referred to for the description of the supporting member 630.

A second semiconductor chip 650 is substantially arranged on a level with the supporting member 630 between the first semiconductor chips 640c and 640d. The second semiconductor chip 650 is electrically connected to the second electrode fingers 618 of the substrate 610 through second connecting members 655. At least a part of the second semiconductor chip 650 vertically overlaps with a part of the first semiconductor chip 640d. A whole part of the second semiconductor chip 650 vertically overlaps with the first semiconductor chip 640c.

A molding member 670 is formed on the substrate 610 and covers a stack structure of the first semiconductor chips 640a through 640f and the second semiconductor chip 650.

According to a modified example of this embodiment, the second semiconductor chip 650 and the supporting member 630 may be substantially arranged on a level between other layers, e.g., the first semiconductor chips 640a and 640b, not between the first semiconductor chips 640c and 640d.

FIG. 13 is a cross-sectional view of a stack module according to an embodiment of the inventive concept. Semiconductor packages of this embodiment may use the semiconductor package of FIG. 6, and thus repeated descriptions will be omitted.

Referring to FIG. 13, a second semiconductor package 520 is stacked above a first semiconductor package 510. The first semiconductor package 510 has a similar structure to the semiconductor package of FIG. 6. However, a substrate 210 further includes bump pads 219 which are formed on a lower surface of the substrate 210 and in a second resin layer 206, and first bumps 290 are connected to the bump pads 219. A re-wiring line 280 is further arranged on a first semiconductor chip 240h which is arranged on an uppermost layer and is electrically connected to the first semiconductor chip 240h.

The second semiconductor package 520 includes a third substrate 210a2 and third semiconductor chips 240a2 through 240h2 which are sequentially stacked above the third substrate 210a2. The third semiconductor chips 240a2 through 240h2 are connected to the third substrate 210a2 through third connecting lines 245c. The third substrate 210a2 is connected to the re-wiring line 280 of the first semiconductor package 510 through second bumps 290a2. Thus, the second semiconductor package 520 is electrically connected to the first semiconductor package 510. In other words, the third semiconductor chips 240a2 through 240h2 are electrically connected to first semiconductor chips 240a through 240h.

Accordingly, as illustrated in FIG. 13 the semiconductor chips 240a through 240h and semiconductor chips 240a2 through 240h2 are in a stair-step arrangement in each of the packages 510 and 520, which alternatingly reverses direction. In particular, the stair-step arrangement includes two steps in the horizontal direction, then is reversed in the opposite direction for two steps, which is then repeated. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

One or more semiconductor packages (not shown) may be further stacked above the second semiconductor package 520.

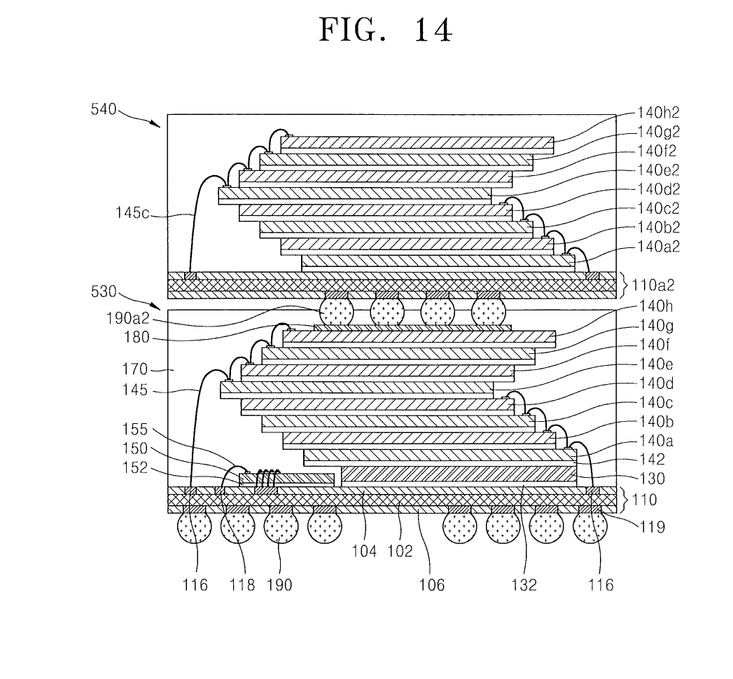

FIG. 14 is a cross-sectional view of a stack module according to another embodiment of the inventive concept. Semiconductor packages of this embodiment may use the semiconductor package of FIG. 1, and thus repeated descriptions will be omitted.

Referring to FIG. 14, a second semiconductor package 540 is stacked above a first semiconductor package 530. The first semiconductor package 530 substantially has a similar structure to the semiconductor package of FIG. 1. However, a substrate 110 further includes bump pads 119 which are formed in a lower surface of the substrate 110 and in a second resin layer 106, and first bumps 190 are connected to the bump pads 119. A re-wiring line 180 is further arranged on a first semiconductor chip 140h which is arranged on an uppermost layer and is electrically connected to the first semiconductor chip 140h.

The second semiconductor package 540 includes a third substrate 110a2 and third semiconductor chips 140a2 through 140h2 which are sequentially stacked above the third substrate 110a2. The third semiconductor chips 140a2 through 140h2 are connected to the third substrate 110a2 through third connecting lines 145c. The third substrate 110a2 is connected to the re-wiring line 180 of the first semiconductor package 530 through second bumps 190a2. Thus, the second semiconductor package 540 is electrically connected to the first semiconductor package 530. In other words, the third semiconductor chips 142a2 through 140h2 are electrically connected to first semiconductor chips 140a through 140h.

Accordingly, as illustrated in FIG. 14 the semiconductor chips 140a through 140h and semiconductor chips 140a2 through 140h2 are in a stair-step arrangement in each of the packages 530 and 540, which alternatingly reverses direction. In particular, the stair-step arrangement includes two steps in the horizontal direction, then is reversed in the opposite direction for two steps, which is then repeated. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

One or more semiconductor packages (not shown) may be further stacked above the second semiconductor package 540.

FIG. 15 is a cross-sectional view of a semiconductor package according to another embodiment of the inventive concept. The semiconductor package of this embodiment has a similar structure to the semiconductor package of FIG. 6 except for some elements, and thus repeated descriptions will be omitted.

Referring to FIG. 15, first semiconductor chips 240a through 240h are vertically arranged. For example, the first semiconductor chips 240a through 240h are the same types of products, have the same sizes, and include sidewalls that are vertically aligned with one another. In this case, first connecting members 245d are connected from electrode pads (not shown) to a substrate 210 through adhesive members 242.

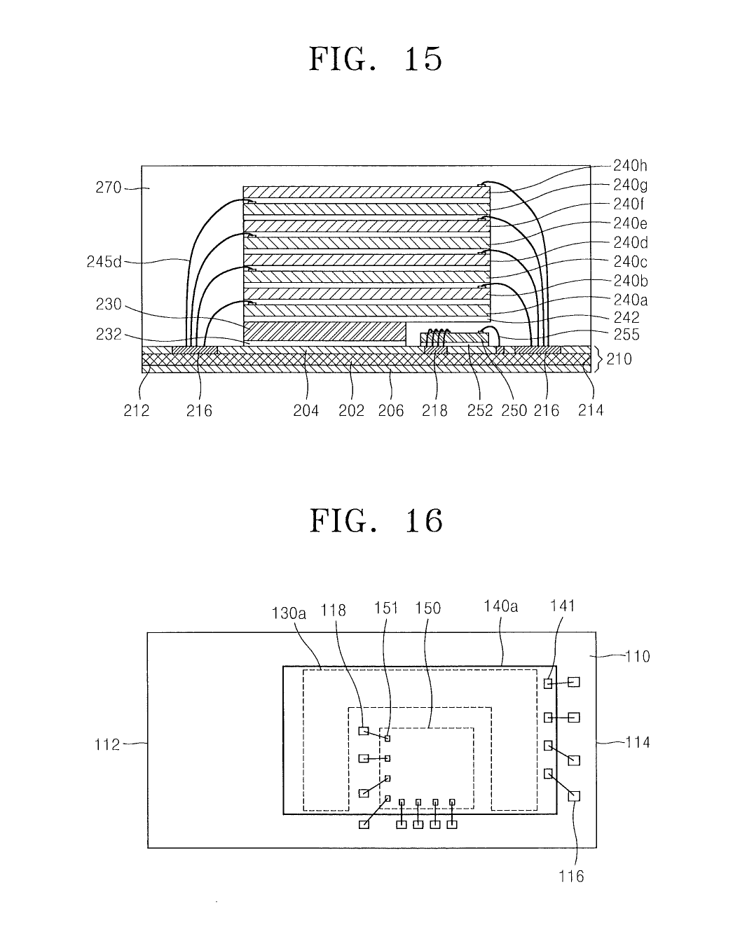

FIGS. 16 through 18 and FIGS. 20 through 22 are plan views illustrating supporting members of semiconductor packages, according to embodiments of the inventive concept, and FIG. 19 is a perspective view of the supporting member of FIG. 18.

Referring to FIG. 16, a supporting member 130a has a polygonal or circular cylindrical shape and includes an opening therein and is shaped to define an interior void. A second semiconductor chip 150 is arranged in the void. A first semiconductor chip 140a covers the supporting member 130a and a part or a whole part of the second semiconductor chip 150. A molding member (170 of FIG. 1) penetrates through the opening in the supporting member 130a.

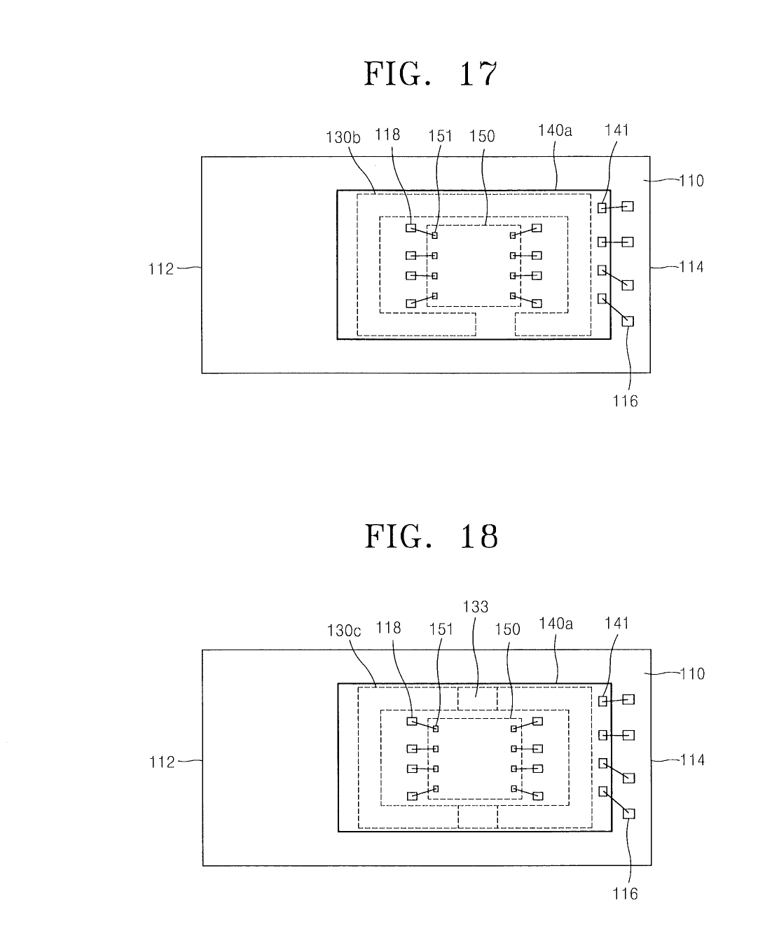

Referring to FIG. 17, a supporting member 130b has a polygonal or circular cylindrical shape and includes an opening therein and defines an interior void. A second semiconductor chip 150 is arranged in the void. A first semiconductor chip 140a covers the supporting member 130b and a part or a whole part of the second semiconductor chip 150. A molding member (170 of FIG. 1) penetrates through the opening in the supporting member 130b.

Referring to FIGS. 18 and 19, a closed supporting member 130c has a polygonal or circular cylindrical shape and defines an interior void. The closed supporting member 130c has at least one recessed portion 133 through which a molding member (170 of FIG. 1) penetrates into the void. In some embodiments, the closed supporting member 130c includes recesses in the surfaces thereof that face the electrically active first semiconductor chip 140a, included in the vertical stair-step arrangement shown, for example, in FIG. 1. and other arrangements shown in the other FIGs.

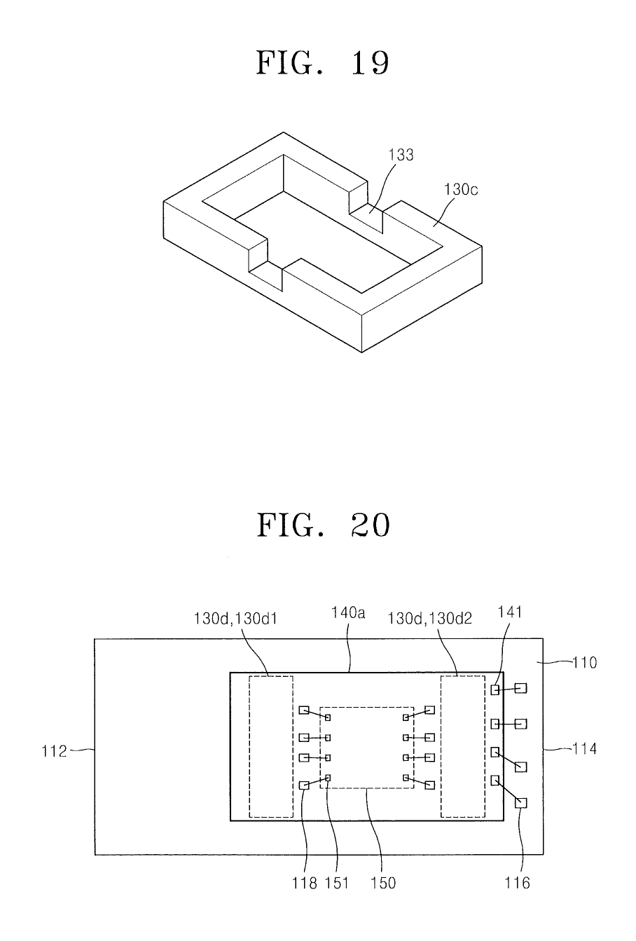

Referring to FIG. 20, a supporting member 130d includes first and second supporting segments 130d1 and 130d2 which are spaced apart from each other around a second semiconductor chip 150. For example, the first and second supporting segments 130d1 and 130d2 are respectively arranged beside both sides of the second semiconductor chip 150 and are symmetrical to each other based on a center of a first semiconductor chip 140a. The supporting member 130d having this symmetrical structure equally distribute a force and thus stably support the first semiconductor chip 140a.

As shown in FIG. 20, the supporting member 130d includes two opposing separate support structures that define an interior void therebetween in which the second semiconductor chip 150 can be located. In some embodiments, two opposing separate support structures are included in the vertical stair-step arrangement shown, for example, in FIG. 1. and other arrangements shown in the other FIGs.

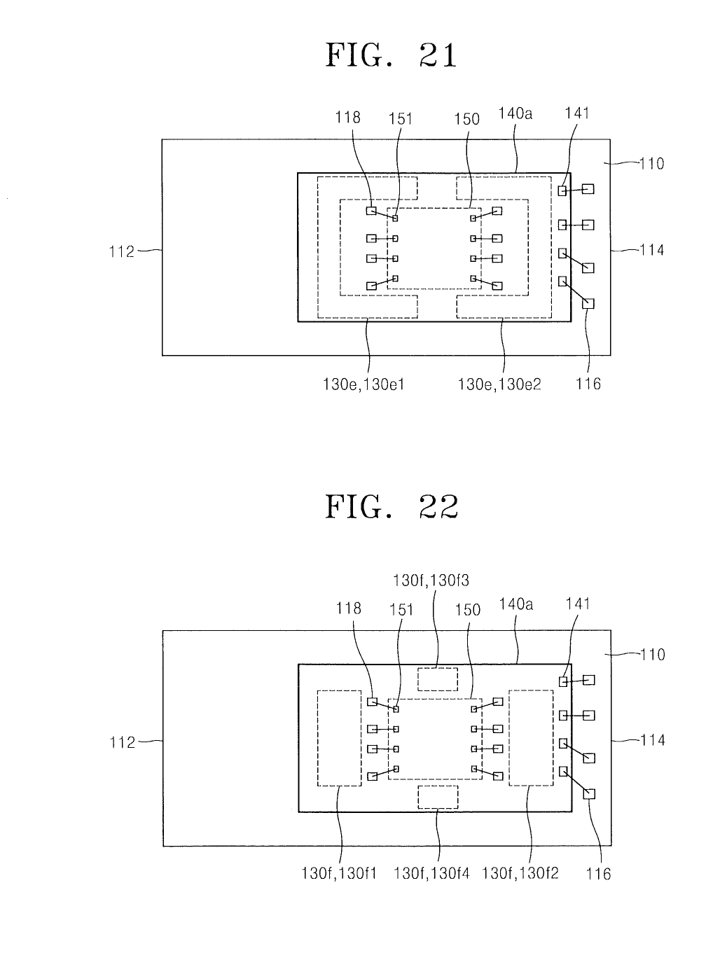

Referring to FIG. 21, a supporting member 130e includes first and second C-shaped support segments 130e1 and 130e2 which are spaced apart from each other around a second semiconductor chip 150. For example, the first and second supporting segments 130e1 and 130e2 enclose the second semiconductor chip 150 and are symmetrical to each other based on a center of a first semiconductor chip 140a.

As shown in FIG. 21, the supporting member 130e includes two opposing separate C-shaped support structures that define an interior void therebetween in which the second semiconductor chip 150 can be located. In some embodiments, the two opposing separate C-shaped support structures are included in the vertical stair-step arrangement shown, for example, in FIG. 1. and other arrangements shown in the other FIGs.

Referring to FIG. 22, a supporting member 130f includes first, second, third, and fourth supporting segments 130f1, 130f2, 130f3, and 130f4 which are spaced apart from one another around a second semiconductor chip 150. For example, the first, second, third, and fourth supporting segments 130f1, 130f2, 130f3, and 130f4 are symmetrical to one another based on a center of a first semiconductor chip 140a.

As shown in FIG. 22, the supporting member 130f includes two pairs of opposing separate support structures that define an interior void therebetween in which the second semiconductor chip 150 can be located. In some embodiments, the two pairs of opposing separate support structures are included in the vertical stair-step arrangement shown, for example, in FIG. 1. and other arrangements shown in the other FIGs.

The supporting members 130a through 130f of FIGS. 16 through 22 have been described with reference to FIG. 2 for convenience but may be applied to other embodiments. At least one of first semiconductor chips 140b through 140h may be further stacked above the first semiconductor chip 140a as shown in FIG. 1.

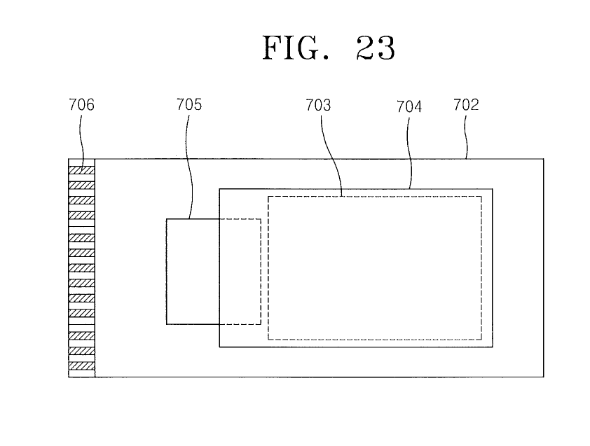

FIG. 23 is a plan view of a card according to an embodiment of the inventive concept. Referring to FIG. 23, a supporting member 703 and a second semiconductor chip 705 are sequentially stacked above a substrate 702. A first semiconductor chip 704 is stacked above the supporting member 703. The description of the substrate 110 of FIG. 1 may be referred to for the description of the substrate 702, and the description of the supporting member 130 of FIG. 1 may be referred to for the description of the supporting member 703. The first semiconductor chip 704 may has a stack structure of the first semiconductor chip 140a or the first semiconductor chips 140a through 140h of FIG. 1. The description of the second semiconductor chip 150 of FIG. 1 may be referred to for the description of the second semiconductor chip 705.

Terminals 706 are arranged at an end of the substrate 702. The terminals 706 are used as input and output ports of the card and thus are electrically connected to the second semiconductor chip 705.

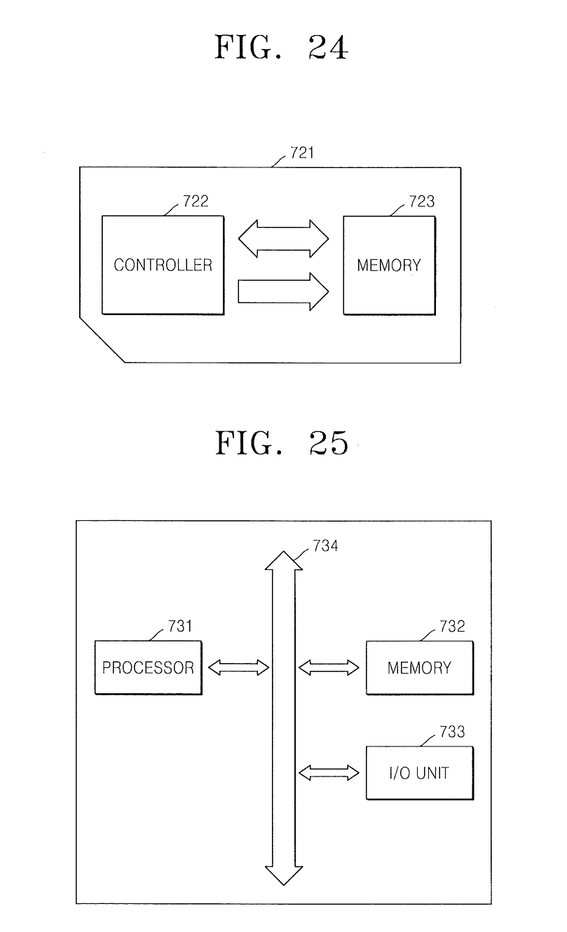

FIG. 24 is a schematic block diagram of a memory card according to an embodiment of the inventive concept. Referring to FIG. 24, the memory card includes a housing 721 which includes a controller 722 and a memory unit 723. The controller 722 controls the memory unit 723 to input and output data. For example, the controller 722 transmits a command to the memory unit 723 to interchange data with the memory unit 723. Thus, the memory card stores the data in the memory unit 723 or outputs the data from the memory unit 723 to an external device.

For example, the memory unit 723 may include at least one of the semiconductor packages and the stack modules which have been described above. The memory card may be used as a data storage medium of various types of portable devices. For example, the memory card may include a multimedia card (MMC) or a secure digital (SD) card.

FIG. 25 is a block diagram of an electronic system according to an embodiment of the inventive concept. Referring to FIG. 25, the electronic system includes a processor 731, an input/output unit 733, and a memory unit 732 which communicate data to one another through a bus 734. The processor 731 executes a program and controls the electronic system. The input/output unit 733 is used to input and/or output the data. The electronic system is connected to an external device, e.g., a personal computer (PC) or a network, through the input/output unit 733 and thus interchanges the data with the external device. The memory unit 732 stores a code and data for an operation of the processor 731. For example, the memory unit 732 may include at least one of the semiconductor packages and the stack modules which have been described above.

The electronic system of this embodiment may constitute various types of electronic control devices, e.g., may be used in a mobile phone, an MP3 player, a navigation system, a solid state disk (SSD), or household appliances.

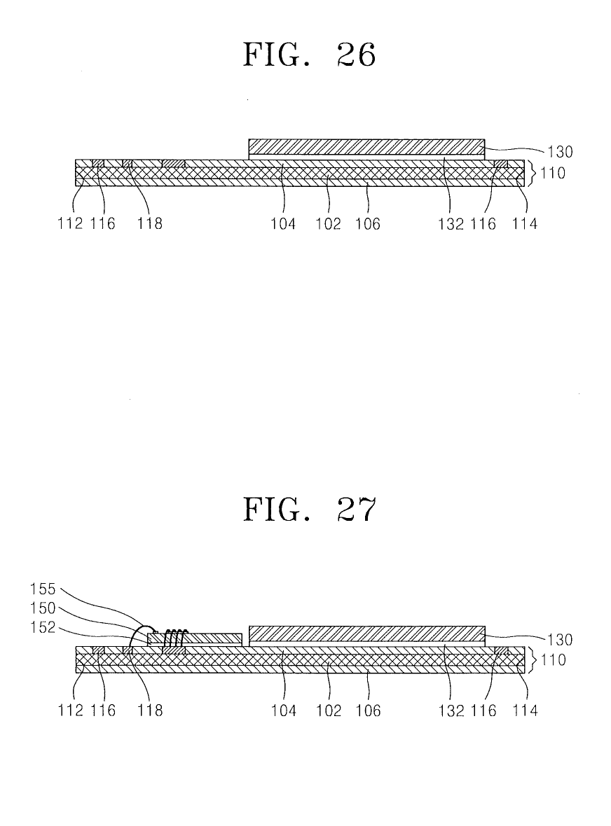

FIGS. 26 through 29 are cross-sectional views illustrating a method of fabricating a semiconductor package according to an embodiment of the inventive concept. Referring to FIG. 26, a supporting member 130 is stacked above a substrate 110 using an adhesive member 132.

Referring to FIG. 27, a second semiconductor chip 150 is substantially stacked on a level with the supporting member 130 above the substrate 110 and thus is adjacent to the supporting member 130. The second semiconductor chip 150 is connected to second electrode fingers 118 of the substrate 110 using a wire bonding method.

Referring to FIG. 28, first semiconductor chips 140a through 140h are stacked and offset above the supporting member 130. In this case, a part of the second semiconductor chip 150 vertically overlaps with a part of the first semiconductor chip 140a, and a whole part of the second semiconductor chip 150 vertically overlaps with a part of the first semiconductor chip 140e.

The first semiconductor chips 140a through 140h are connected to first electrode fingers 116 of the substrate 110 through first connecting members 145 using a wire bonding method.

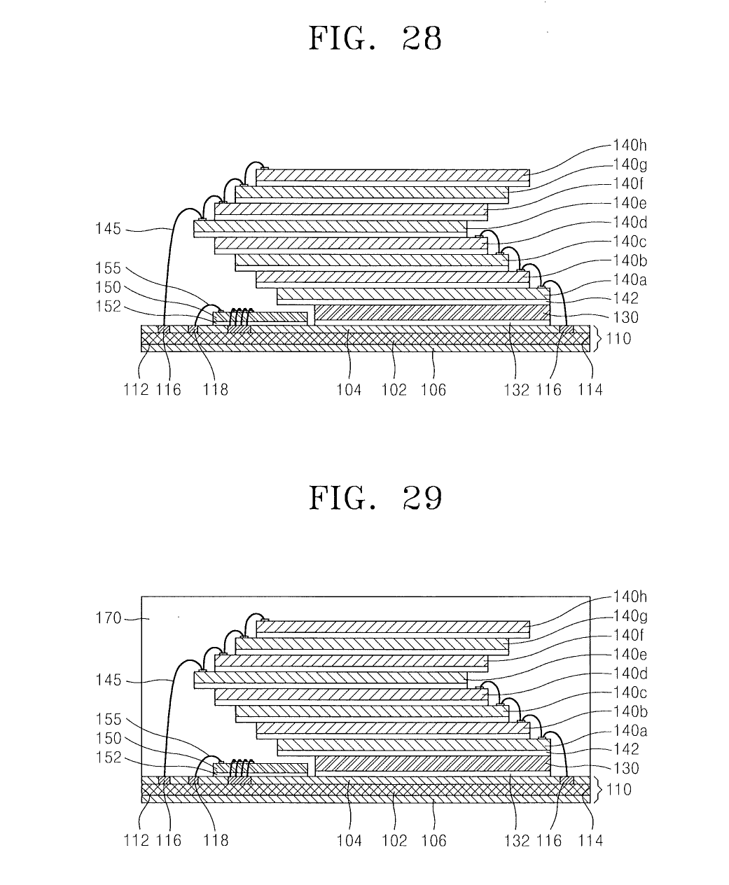

Referring to FIG. 29, a molding member 170 is formed on the substrate 110 and covers the first semiconductor chips 140a through 140h and the second semiconductor chip 150.

Accordingly, as illustrated in FIG. 29 the first semiconductor chips 140a through 140h are in a stair-step arrangement, which alternatingly reverses direction. In particular, the stair-step arrangement includes two steps in the horizontal direction, then is reversed in the opposite direction for two steps, which is then repeated. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

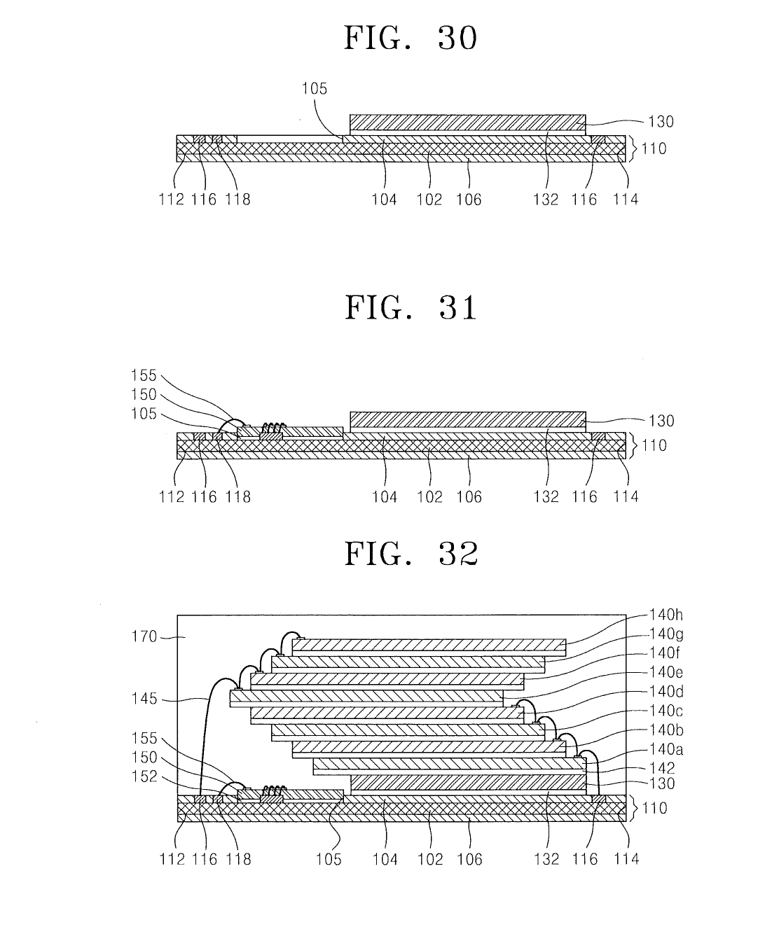

FIGS. 30 through 32 are cross-sectional views illustrating a method of fabricating a semiconductor package according to another embodiment of the inventive concept.

Referring to FIG. 30, a supporting member 130 is stacked above a substrate 110 using an adhesive member 132. A first resin layer 104 is patterned to form an opening 105 inside the first resin layer 104, wherein the opening 105 is adjacent to the supporting member 130.

Referring to FIG. 31, a second semiconductor chip 150 is stacked in the opening 105. Thus, the second semiconductor chip 150 is arranged under the supporting member 130 by a depth of the opening 105. The second semiconductor chip 150 is connected to second electrode fingers 118 of the substrate 110 using a wire bonding method.

Referring to FIG. 32, first semiconductor chips 140a through 140h are stacked and offset above the supporting member 130. The first semiconductor chips 140a through 140h are connected to first electrode fingers 116 of the substrate 110 through first connecting members 145 using a wire bonding method. A molding member 170 is formed on the substrate 110 and covers the first semiconductor chips 140a through 140h and the second semiconductor chip 150.

Accordingly, as illustrated in FIG. 32 the first semiconductor chips 140a through 140h are in a stair-step arrangement, which alternatingly reverses direction. In particular, the stair-step arrangement includes two steps in the horizontal direction, then is reversed in the opposite direction for two steps, which is then repeated. The stair-step arrangement can provide that the sidewalls of the chips are progressively offset from one another in a first dimension (such as the horizontal dimension) so that respective pads located on the chips are sufficiently exposed to allow for contact by, for example, wires. Further, as shown, the stair-step arrangement can alternate in the horizontal direction to reduce the need for the package size to be increased while still allowing access to the pads.

While the inventive concept has been particularly shown and described with reference to exemplary embodiments thereof, it will be understood that various changes in form and details may be made therein without departing from the spirit and scope of the following claims.

What is claimed:

1. A multi-chip package device including a plurality of integrated circuit device chips stacked on one another inside a multi-chip package including the device, the device comprising:
an electrically isolated multi-chip support structure directly connected to first and second electrically active integrated circuit structures via respective first and second adhesive layers located on opposing sides of the electrically isolated multi-chip support structure.

2. A multi-chip package device according to claim 1 wherein the first electrically active integrated circuit structure comprises a substrate including active integrated circuits and the second electrically active integrated circuit structure comprises one of the plurality of integrated circuit device chips.

3. A multi-chip package device according to claim 1 wherein the first electrically active integrated circuit structure comprises a first one of the plurality of integrated circuit device chips and the second electrically active integrated circuit structure comprises a second one of the plurality of integrated circuit device chips.

4. A multi-chip package device according to claim 3 further comprising:
a substrate including active integrated circuits, the substrate located beneath the plurality of integrated circuit device chips and directly connected thereto via a third adhesive layer therebetween.

5. A multi-chip package device according to claim 1 wherein the electrically isolated multi-chip support structure is smaller than the second electrically active integrated circuit structure in a first dimension so that a portion of the second electrically active integrated circuit structure is cantilevered over the first electrically active integrated circuit structure to form a recess therebetween that is bounded in the first dimension by a sidewall of the electrically isolated multi-chip support structure.

6. A multi-chip package device according to claim 5 wherein the sidewall of the electrically isolated multi-chip support structure comprises a first sidewall, the device further comprising:
a second sidewall of the electrically isolated multi-chip support structure opposite the first sidewall aligned to a sidewall of the second electrically active integrated circuit structure.

7. A multi-chip package device according to claim 5 wherein the sidewall of the electrically isolated multi-chip support structure comprises a first sidewall, the device further comprising:
a second sidewall of the electrically isolated multi-chip support structure opposite the first sidewall recessed from a sidewall of the second electrically active integrated circuit structure toward the first sidewall.

8. A multi-chip package device according to claim 1 wherein the support structure includes no active integrated circuits.

9. A multi-chip package device according to claim 1 wherein the support structure comprises:
a closed support structure defining an interior void.

10. A multi-chip package device according to claim 9 wherein the closed support structure includes recesses in at least one surface facing the first or second electrically active integrated circuit structure on opposing sides of the closed support structure to allow access to the interior void from outside the closed support structure.

11. A multi-chip package device according to claim 1 wherein the support structure comprises:
at least two opposing separate support structures defining an interior void therebetween.

12. A multi-chip package device according to claim 11 wherein the at least two opposing separate support structures comprise two opposing separate C-shaped support structures.

13. A multi-chip package device according to claim 11 wherein the at least two opposing separate support structures comprise two pairs of opposing separate support structures.

14. A multi-chip package device including a plurality of integrated circuit device chips stacked on one another inside a multi-chip package including the device, the device comprising:
a multi-chip support structure electrically isolated from the plurality of integrated circuit device chips and from an underlying substrate; and
an adhesive layer directly connecting the multi-chip support structure to the substrate.

15. A multi-chip package device according to claim 14 wherein the substrate includes active integrated circuits.

16. A multi-chip package device according to claim 14 wherein the adhesive layer comprises a first adhesive layer, the device further comprising:
a second adhesive layer, opposite the first adhesive layer, directly connecting a first one of the plurality of integrated circuit device chips to the multi-chip support structure opposite the substrate.

17. A multi-chip package device according to claim 16 wherein a region between the second adhesive layer and the first one of the plurality of integrated circuit device chips is free of an encapsulating material.

18. A multi-chip package device comprising:
a plurality of integrated circuit device chips stacked on one another inside a multi-chip package including the device in a stair-step arrangement;
a substrate electrically connected to at least one of the plurality of integrated circuit device chips;
a support structure between the plurality of integrated circuit device chips and the substrate; and
an adhesive layer directly on the support structure and directly on the substrate.

19. A multi-chip package device according to claim 18 wherein the substrate includes active integrated circuits.

20. A multi-chip package device according to claim 18 wherein the adhesive layer comprises a first adhesive layer, the device further comprising:
a second adhesive layer, opposite the first adhesive layer, directly connecting a first one of the plurality of integrated circuit device chips to the support structure opposite the substrate.

21. A multi-chip package device according to claim 20 wherein a region between the second adhesive layer and the first one of the plurality of integrated circuit device chips is free of an encapsulating material.
